(19) United States
(12) Patent Application Publication
(10) Pub. No.: US 2008/0135278 A1
(43) Pub. Date: Jun. 12, 2008

(54) PRINTED BOARD

(75) Inventor: Hiroaki Abe, Kawasaki (JP)

Correspondence Address: KATTEN MUCHIN ROSENMAN LLP, 575 MADISON AVENUE, NEW YORK, NY, 10022-2585, US

(73) Assignee: FUJITSU LIMITED, Kawasaki-shi (JP)

(21) Appl. No.: 11/949,840

(22) Filed: Dec. 4, 2007

(30) Foreign Application Priority Data
Dec. 12, 2006 (JP) 2006-334495

(51) Int. Cl. H05K 1/00; H05K 1/16

(52) U.S. Cl. 174/250; 174/260

(57) ABSTRACT

To provide a multivendor-compatible printed board. On one face of an IVH (Interstitial Via Hole) board, wiring is provided for mounting a first semiconductor device, and on the other face, wiring is provided for mounting a second semiconductor device having pin positions and pin counts different from the first semiconductor. By the IVH board according to the present invention, one face can be used for mounting the first semiconductor device, and the other face can be used for mounting the second semiconductor device. Thus, even when the semiconductor device mounted on the IVH board of the present invention is changed, it becomes possible to use the identical board.

### CROSS-REFERENCE TO RELATED APPLICATIONS

This application is based upon and claims the benefit of priority from the prior Japanese Patent Application No. 2006-334495, filed on Dec. 12, 2006, the entire contents of which are incorporated herein by reference.

### BACKGROUND OF THE INVENTION

1. Field of the Invention

The present invention relates to a multilayer printed board to mount a semiconductor device such as a PLD (Programmable Logic Device), and more particularly, a printed board capable of mounting a plurality of PLDs having different pin counts and pin positions, enabling production at low cost.

2. Description of the Related Art

In recent years, as a principal semiconductor device configuring hardware, a PLD (Programmable Logic Device) has been used. The PLD (Programmable Logic Device) is a semiconductor device of which logic circuit structure can be modified by programming, and is a kind of semi-custom LSI. Since the development and manufacturing period can be shortened, and specialization to individual use can be attained with reduced cost, the market tends to increase because of convenience thereof. There are a variety of PLD types, such as PAL (Programmable Array Logic), GAL (Generic Array Logic), CPLD (Complex Programmable Logic Device), and FPGA (Field Programmable Gate Array).

The PLD is mounted on a printed board. However, because there are supplied a variety of types of PLDs having different specifications, vendor by vendor, on the counts and positions of pins, it is necessary to develop a printed board to fit the specification of the PLD to be mounted.

FIG. 1 shows a printed board having a PLD mounted thereon, according to the prior art. For example, on one face of a through-hole board 5 having a plurality of laminated signal wiring layers (in FIG. 1, two layers on each side, as an example), there are mounted a PLD 2 and a peripheral circuit 1 to be connected thereto. Through-hole board 5 is required to be designed so that through-hole positions and wiring fit the specification of PLD 2 to be mounted, such as pin counts and pin positions. In case of the through-hole board, the through holes on both faces are positioned in identical position. Therefore, in place of PLD 2 originally mounted on one face, when it is intended to mount another PLD 2 having different pin counts and pin positions on the other face, the pin positions may not fit. To fit the pin positions, extra wiring is required on the surface of the other face to connect the pins to the through-holes. The above extra wiring may produce a different wiring length on one face from the other, which may cause a risk leading to delay and deviation in a signal transmission time.

In the following Patent document 1, there is disclosed a structure in which general-purpose semiconductor devices are mounted on either side of a multilayer wiring board, having three-dimensional wiring by use of inner via holes, and disposed oppositely via the multilayer wiring board, so as to connect the electrode terminals of both semiconductor devices.

[Patent document 1] the official gazette of the Japanese Unexamined Patent Publication No. Hei-11-154728.

Recently, technical progress of the PLD is remarkable, and the PLD price decreases as new devices of fine process appear. Therefore, from the viewpoint of cost reduction in equipment development, a case is assumed that a PLD mounted on the equipment to be developed is replaced by another PLD of which cost is lower. However, when it is intended to use the other PLD by changing the PLD vendor, it becomes necessary to develop a new printed board for mounting the other PLD. Namely, the PLD after the change usually has different specifications in pin counts and pin positions from the PLD before the change. Since the printed board is produced to fit the PLD specifications to be mounted, when the PLD vendor is changed, the printed board produced to enable mounting of the PLD before the change can no more be used. As described above, when a through-hole board is used, it is virtually impossible to cope with a plurality of types of PLDs having different pin positions and pin counts.

As a result, it becomes necessary to newly develop a printed board capable of mounting the other PLD of interest. Even if the PLD cost is decreased, the development cost of the printed board arises, which becomes an obstacle to the total cost reduction in developing the equipment. Therefore, in order to have a single printed board compatible with PLDs from different vendors, it is desired to obtain a multivendor-compatible printed board.

### SUMMARY OF THE INVENTION

Accordingly, it is an object of the present invention to provide a multivendor-compatible printed board, capable of mounting semiconductor devices of different types.

As a printed board structure according to the present invention to achieve the aforementioned object, the printed board includes: a first face including a first signal wiring layer surface having a formed wiring pattern capable of mounting a first semiconductor device, and a common signal wiring layer surface having a formed wiring pattern capable of mounting a first circuit; and a second face, which is an opposite face to the first face, including a second signal wiring layer surface having a formed wiring pattern capable of mounting a second semiconductor device. The above first signal wiring layer and the second signal wiring layer are electrically separated, and the above common signal wiring layer is electrically connectable to either one of the first signal wiring layer and the second signal wiring layer.

As another printed board structure according to the present invention, the printed board includes: a first face including a common signal wiring layer surface having a formed wiring pattern capable of mounting a first circuit; and a second face, which is an opposite face to the first face, having a buildup layer surface built up on the opposite face side to the common signal wiring layer surface. The above buildup layer is a signal wiring layer having a formed wiring pattern to enable a semiconductor device being mounted on the buildup layer to be electrically connected to the common signal wiring layer.

Further scopes and features of the present invention will become more apparent by the following description of the embodiments with the accompanied drawings.

### BRIEF DESCRIPTION OF THE DRAWINGS

FIG. 1 shows a printed board having a PLD mounted thereon, according to the prior art.

FIGS. 2A, 2B show a first exemplary structure of a printed board according to an embodiment of the present invention.

FIGS. 3A, 3B show a second exemplary structure of a printed board according to an embodiment of the present invention.

FIGS. 4A, 4B show a third exemplary structure of a printed board according to an embodiment of the present invention.

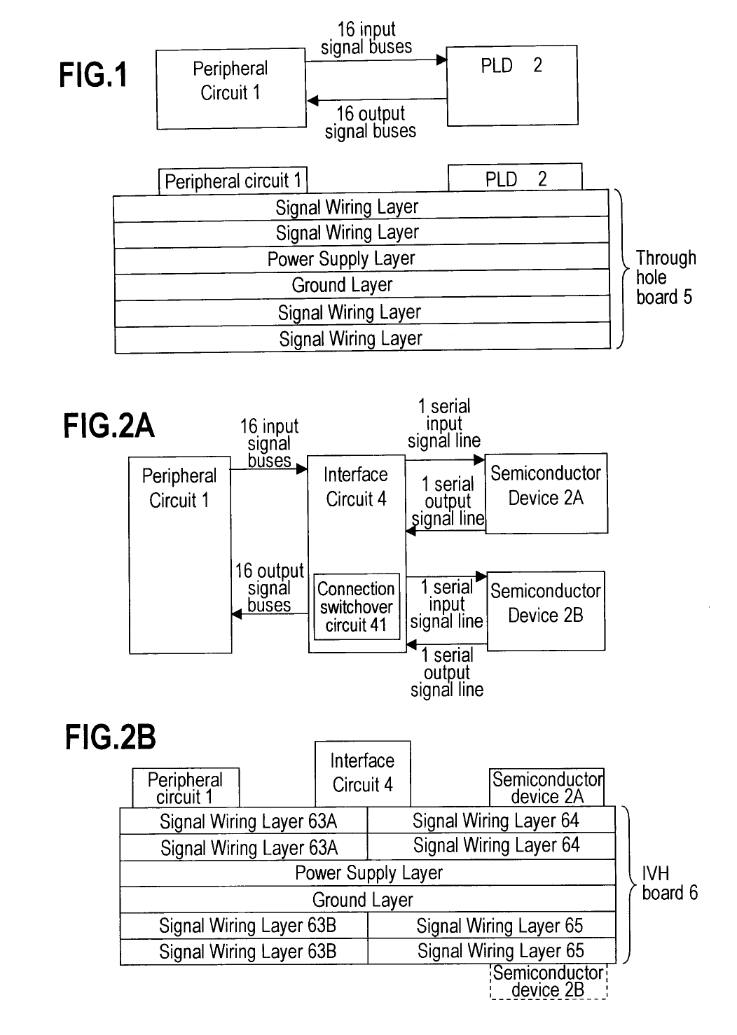

### DETAILED DESCRIPTION OF THE PREFERRED EMBODIMENTS

The preferred embodiments of the present invention are described hereinafter referring to the charts and drawings. However, the embodiments described below are not intended to limit the technical scope of the present invention.

According to the present invention, there is provided a printed board capable of mounting semiconductor devices from different vendors, using an IVH (Interstitial Via Hole) board. The IVH board has a board having an unpenetrated via (interstitial via hole: IVH) for connecting interlayer between two or a plurality of signal layers more than two requiring connection. When the IVH is disposed in the internal layers, the via hole is termed buried via hole, while when one end of the IVH is disposed on a surface layer, the via hole is termed blind via hole. The via is provided only between the signal layers requiring connection, and because the via is not a through hole penetrated through both board faces, it becomes possible to wire independently (electrically separately) on a face-by-face basis, with the provision of vias at different positions.

Using such the characteristic of the IVH board, according to the present invention, there is provided an IVH board having wiring on one face of the IVH board for mounting a first semiconductor device (PLD, for example), and having wiring on the other face for mounting a second semiconductor device (PLD, for example), having different pin positions and pin counts from the first semiconductor device. The first semiconductor device and the second semiconductor device are semiconductor devices from different vendors. Different vendors provide different pin positions and pin counts, and therefore, when it is intended to use a semiconductor device from a different vendor, conventionally, the board to mount the semiconductor device must newly be designed also. However, by use of the IVH board according to the present invention, one face can be used for mounting the first semiconductor device, while the other face can be used for mounting the second semiconductor device. Thus, even when changing the semiconductor device to be mounted on the IVH board according to the present invention, it becomes possible to use the identical board.

Accordingly, it becomes possible to reduce the development cost of a new printed board which may have been required when changing the semiconductor device. Further, because a common board can be used even if the semiconductor device is changed, cost reduction through mass production can be expected.

FIGS. 2A, 2B show a first exemplary structure of a printed board (IVH board) according to an embodiment of the present invention. FIG. 2A is a diagram illustrating a circuit structure mounted on the IVH board, and FIG. 2B is a diagram illustrating a layer structure of the IVH board on which the above circuit is mounted.

In FIG. 2A, a peripheral circuit 1 is connected to either one of semiconductor devices 2A and 2B via an interface circuit 4 in a switchable manner (both are not mounted simultaneously, but one is selected and mounted on a corresponding face). Interface circuit 4 is a parallel/serial converter, which is connected to peripheral circuit 1, for example, through sixteen (16) input signal buses and 16 output signal buses, and connected to semiconductor device 2A or 2B through one input signal line and one output signal line, so as to convert a parallel signal into a serial signal (or convert a serial signal into a parallel signal) by time division processing.

Interface circuit 4 has a connection switchover circuit 41 incorporated therein, for switching the connection to either one of semiconductor devices 2A and 2B. Namely, interface circuit 4 is connected to the semiconductor device side selected by connection switchover circuit 41, whereas electrically insulated from the semiconductor device side not being selected. In short, interface circuit 4 functions as connection switchover circuit 41.

In FIG. 2B, an IVH board 6 includes a power supply layer 61 and a ground layer 62. On the power supply layer 61 side, signal wiring layers 63A and signal wiring layers 64 are laminated in the number of two for each. Also, on the ground layer 62 side, signal wiring layers 63B and signal wiring layers 65 are laminated in the number of two for each. Interlayer connections between any signal wiring layers are made by means of interstitial via holes (IVH).

Signal wiring layers 63A, 63B are layers each having a formed common wiring pattern for connecting peripheral circuit 1 to interface circuit 4. Each signal wiring layer 64 is a layer having a formed wiring pattern for connecting the common wiring pattern to semiconductor device 2A via interface circuit 4. Also, each signal wiring layer 65 is a layer having a formed wiring pattern for connecting the common wiring pattern to semiconductor device 2B via interface circuit 4.

As such, signal wiring layer 64 for semiconductor device 2A is disposed on one face of IVH board 6, while signal wiring layer 65 for semiconductor device 2B is disposed on the other face. Thus, even when the semiconductor device mounted on IVH board 6 is changed from semiconductor device 2A to semiconductor device 2B, by mounting semiconductor device 2B on the other face (the signal wiring layer 65 side) of IVH board 6, and by switching the switchover circuit in interface circuit 4 to connect to semiconductor 2B, IVH board 6 having been used for semiconductor device 2A can now be used for semiconductor device 2B.

When semiconductor device 2B is mounted, connection switchover circuit 41 incorporated in interface circuit 4 is switched over to make signal wiring layer 63 conductive to signal wiring layer 65, whereas signal wiring layer 63 is electrically insulated from signal wiring layer 64. Also, according to the present invention, by using the IVH board, through holes for conducting between signal wiring layer 64 and signal wiring layer 65 are not provided, and signal wiring layer 64 and signal wiring layer 65 are electrically insulated. Accordingly, a signal flowing between interface circuit 4 and semiconductor device 2B via signal wiring layer 65 does not flow in signal wiring layer 64. Assuming that signal wiring layer 64 is not insulated, a radio wave is radiated from an open via on the wiring pattern of signal wiring layer 64 on which semiconductor device 2A is not mounted. The above radiation has a risk of producing bad influence such that noise is generated and malfunction is caused in the circuits existent in the periphery, such as peripheral circuit 1 and interface circuit 4. In the first exemplarily structure, such the inconvenience can be prevented because insulation to the signal wiring layer on the side not having the semiconductor device is intended, by means of connection switchover circuit 41 incorporated in interface circuit 4.

Further, with the provision of interface circuit 4 between peripheral circuit 1 and semiconductor device 2A or 2B, thereby minimizing the number of signal lines of semiconductor device 2A or 2B, the number of use pins of semiconductor device 2A can be minimized, and wiring pattern can be simplified.

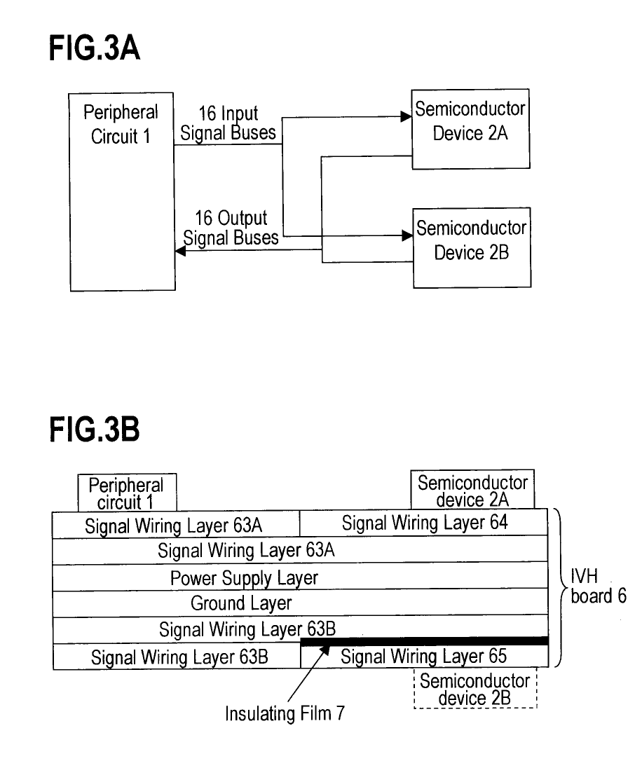

FIGS. 3A, 3B show a second exemplary structure of a printed board (IVH board) according to an embodiment of the present invention. FIG. 3A is a diagram illustrating a circuit structure mounted on the IVH board, and FIG. 3B is a diagram illustrating a layer structure of the IVH board on which the above circuit is mounted.

In FIG. 3A, peripheral circuit 1 is connectable to both semiconductor devices 2A and 2B, through 16 input signal buses and 16 output signal buses, as an example. Namely, as compared to FIG. 2A, peripheral circuit 1 is directly connected to semiconductor device 2A or 2B without intermediary of interface circuit 4.

Because of no provision of interface circuit 4 for converting parallel signals into serial signals, a wiring pattern is formed to have the signal buses of peripheral circuit 1 being made to branch so as to be connected to semiconductor device 2A or 2B. In the above point, the wiring pattern on each signal wiring layer differs from the wiring pattern adopted in FIG. 2A. However, the structure constituting IVH board 6 is substantially identical to the structure shown in FIG. 2B.

More specifically, in FIG. 3B, IVH board 6 includes a power supply layer 61 and a ground layer 62, similar to FIG. 2B. On the power supply layer 61 side, two signal wiring layers 63A are laminated and a signal wiring layers 64 are formed. Also, on the ground layer side, two signal wiring layers 63B are laminated and a signal wiring layers 65 are formed. Interlayer connections between any signal wiring layers are made by means of interstitial via holes (IVH). Each signal wiring layers 63A, 63B includes a common wiring pattern to enable peripheral circuit 1 to connect to the wiring patterns of signal wiring layer 64 and signal wiring layer 65. Signal wiring layer 64 is a layer having a formed wiring pattern for connecting the common wiring pattern of signal wiring layer 63A to semiconductor device 2A. Also, signal wiring layer 65 is a layer having a formed wiring pattern for connecting the common wiring pattern of signal wiring layer 63B to semiconductor device 2B.

In the first exemplary structure, by means of connection switchover circuit 41 incorporated in interface circuit 4, it is intended to insulate from the signal wiring layer on which no semiconductor device is mounted. However, in the second exemplary structure, connection switchover circuit 41 is not provided. Therefore, as shown in FIG. 3B, for example, when semiconductor device 2B is mounted on signal wiring layer 64, and signal wiring layer 65 is not in use, an insulating film 7 is sandwiched between signal wiring layer 65 and signal wiring layer 63B to electrically separate signal wiring layers 63A and 63B from signal wiring layer 65. Thus, radio wave radiation from an open via on signal wiring layer 65 is prevented.

When semiconductor device 2A is mounted on signal wiring layer 65, and signal wiring layer 64 is not in use, insulating film 7 is sandwiched between signal wiring layer 64 and signal wiring layer 63A, so as to prevent radio wave radiation from an open via on signal wiring layer 64.

It is necessary to sandwich insulating film 7 at the manufacturing stage of IVH board 6. Although the position of insulating film 7 differs depending on whether semiconductor devices 2A or 2B is to be mounted on IVH board 6, the structure constituting the signal wiring layer is identical no matter which semiconductor device is mounted. The IVH board corresponding to the changed semiconductor device can be manufactured simply by changing the layout position of insulating film 7.

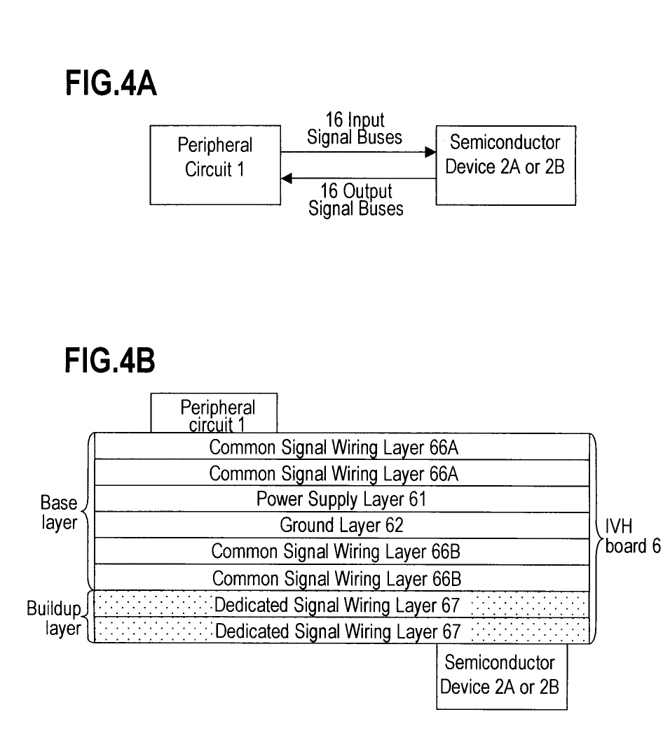

FIGS. 4A, 4B show a third exemplary structure of a printed board (IVH board) according to an embodiment of the present invention. FIG. 4A is a diagram illustrating a circuit structure mounted on the IVH board, and FIG. 4B is a diagram illustrating a layer structure of the IVH board on which the above circuit is mounted.

In FIG. 4A, peripheral circuit 1 is connectable to either one of semiconductor devices 2A and 2B, through 16 input signal buses and 16 output signal buses, as an example. Namely, as compared to FIG. 3A, a wiring pattern is formed to have the signal buses from peripheral circuit 1 not being made to branch, but being connected to either one of semiconductor devices 2A and 2B. Also, without intermediary of interface circuit 4 shown in FIG. 2A, peripheral circuit 1 is directly connected to semiconductor device 2A or 2B.

In FIG. 4B, IVH board 6 includes a power supply layer 61 and a ground layer 62, and on both the power supply layer 61 side and the ground layer 62 side, common signal wiring layers 66A, 66B, having common wiring patterns for connecting peripheral circuit 1, are laminated in the number of two for each. Peripheral circuit 1 is assumed to be mounted on common signal wiring layer 66A. Six layers constituted of power supply layer 61, ground layer 62, and common signal wiring layers 66A, 66B are referred to as a base layer. The base layer includes wiring layers having the common wiring patterns to any semiconductor devices. Further, as a buildup layer in IVH board 6, when semiconductor device 2A is mounted, a dedicated signal wiring layer 67 to enable mounting semiconductor device 2A is laminated, while when semiconductor device 2B is mounted, another dedicated signal wiring layer 67 to enable mounting semiconductor device 2B is laminated.

Each dedicated signal wiring layer 67 is the signal wiring layer for connecting common signal wiring layer 66B to semiconductor device 2A or 2B, and is formed to be the buildup layer in IVH board 6.

The buildup layer is a wiring layer additionally laminated to the base layer at the time of manufacturing the IVH board, when the standard number of layers (for example, 6 layers, 12 layers, or the like) ordinarily used is not sufficient. Depending on the necessity, the IVH board having the laminated buildup layer can be manufactured. In the third exemplary structure, as the buildup layer of IVH board 6, there is laminated a conversion layer having a conversion wiring pattern for converting the wiring pattern of common signal wiring layer 66B into a wiring pattern dedicated to the semiconductor device to be mounted. Namely, the buildup layer includes the conversion wiring pattern for electrically connecting the semiconductor device, being mounted on the buildup layer concerned, to the common wiring pattern.

When changing the semiconductor device to be mounted, there is no need of redesigning from the first. Namely, IVH board 6 including a buildup layer laminated on the base layer, having the conversion wiring pattern corresponding to the semiconductor device to be mounted, is manufactured without any modification of the base layer having the common wiring pattern for connecting to peripheral circuit 1. Thus, it is possible to manufacture IVH board 6 corresponding to the semiconductor device to be mounted. By forming the IVH board as shown in the third exemplary structure, it is possible to easily manufacture the IVH board dedicated to the semiconductor device to be mounted.

When changing the semiconductor device to be mounted, conventionally, on a printed board having a wiring pattern designed for the semiconductor device before the change, there has been a method of mounting a conversion board for converting the above wiring pattern into a wiring pattern designed for a semiconductor device after the change. Then, the semiconductor device after the change is mounted on the above conversion board. However, in the above conventional method, it is necessary to newly manufacture the conversion board in addition to manufacturing the original printed board, which causes increased cost.

Further, the wiring pattern before the change differs depending on a semiconductor device type having been used, and the wiring pattern for conversion is required to redesign each time, according to the wiring pattern before the change.

In contrast, according to the third exemplary structure, the common wiring pattern on the base layer is common to any semiconductor devices. Therefore, in designing the wiring pattern corresponding to the semiconductor device to be mounted, only the conversion from the common wiring pattern is required. Moreover, the lamination of the buildup layer is one of the processes to manufacture a board. As compared to special manufacturing of the conversion board, there are remarkable merits in workload and cost.

Further, instead of the IVH board in the first and second exemplary structures, which enables mounting a plurality of semiconductor devices, the IVH board according to the third exemplary structure is formed to mount only a single semiconductor device. Therefore, an open via does not exist, nor occurs the problem caused by radio wave radiation.

As such, according to the present invention, it becomes possible to obtain a multivendor-compatible printed board. When the semiconductor device mounted on the printed board is to be changed, the development of a new printed board to follow the change can be eliminated. Thus, rapid device change can be performed at low cost, and the cost reduction in developing a new printed board and a product obtained through the common use of the printed board can be attained.

The foregoing description of the embodiments is not intended to limit the invention to the particular details of the examples illustrated. Any suitable modification and equivalents may be resorted to the scope of the invention. All features and advantages of the invention which fall within the scope of the invention are covered by the appended claims.

What is claimed is:

1. A printed board comprising:
a first face including a first signal wiring layer surface having a formed wiring pattern capable of mounting a first semiconductor device, and a common signal wiring layer surface having a formed wiring pattern capable of mounting a first circuit; and
a second face, an opposite face to the first face, including a second signal wiring layer surface having a formed wiring pattern capable of mounting a second semiconductor device,
wherein the first signal wiring layer and the second signal wiring layer are electrically separated, and the common signal wiring layer is electrically connectable to either one of the first signal wiring layer and the second signal wiring layer.

2. The printed board according to claim 1,
wherein a connection switchover circuit is mounted thereon for electrically connecting the common signal wiring layer to either one of the first signal wiring layer and the second signal wiring layer, and for electrically separating the common signal wiring layer from the other signal wiring layer.

3. The printed board according to claim 1,
wherein a conversion circuit is mounted thereon for converting a parallel signal transmitted on the common signal wiring layer into a serial signal, so as to transfer to the first signal wiring layer and the second signal wiring layer, and for converting a serial signal transmitted on either one of the first signal wiring layer and the second signal wiring layer into a parallel signal, so as to transfer to the common signal wiring layer.

4. The printed board according to claim 1, further comprising:
an insulating film sandwiched between the common signal wiring layer and either one of the first signal wiring layer and the second signal wiring layer,
wherein the common signal wiring layer is electrically separated from either one of the first signal wiring layer and the second signal wiring layer, and electrically connected to the other thereof.

5. A printed board comprising:
a first face including a common signal wiring layer surface having a formed wiring pattern capable of mounting a first circuit; and
a second face, an opposite face to the first face, having a buildup layer surface built up on the opposite face side to the common signal wiring layer surface,
wherein the buildup layer is a signal wiring layer having a formed wiring pattern to enable a semiconductor device being mounted on the buildup layer to be electrically connected to the common signal wiring layer.

6. The printed board according to claim 1,
wherein the printed board is an interstitial via hole board.
